(19) United States
(12) Patent Application Publication
(10) Pub. No.: US 2014/0152389 A1
(43) Pub. Date: Jun. 5, 2014

(54) Actively Tuned Circuit Having Parallel Carrier and Peaking Paths

(71) Applicant: Simon H. Hamparian, Emerson, NJ (US)

(72) Inventor: Simon H. Hamparian, Emerson, NJ (US)

(73) Assignee: Andrew LLC, Hickory, NC (US)

(21) Appl. No.: 13/504,978

(22) PCT Filed: Jul. 25, 2011
(86) PCT No.: PCT/US11/45173

§ 371 Date: Apr. 30, 2012

(51) Int. Cl. H03F 3/68; H03F 3/21

(52) U.S. Cl. CPC H03F 3/68; H03F 3/211
USPC 330/295

(57) ABSTRACT

A (e.g., Doherty) circuit with carrier and peaking amplifier paths, has an independently controlled, variable phase shifter in each of those signal processing paths that is controlled to compensate for distortion resulting from operating at frequencies that are relatively far from the optimal (e.g., center) frequency of the circuit's operating bandwidth.

### BACKGROUND

1. Field of the Invention

The present invention relates to electronics and, more specifically but not exclusively, to Doherty circuits.

2. Description of the Related Art

This section introduces aspects that may help facilitate a better understanding of the invention. Accordingly, the statements of this section are to be read in this light and are not to be understood as admissions about what is prior art or what is not prior art.

FIG. 1 shows a conventional Doherty circuit 100 where the input splitter 110 is an in-phase Wilkinson power splitter. In one implementation, Doherty circuit 100 receives an RF input signal 105 and produces a corresponding (e.g., amplified) RF output signal 195. Input splitter 110 splits the RF input signal evenly into two paths: a carrier amplifier path 120 and a peaking amplifier path 130. The carrier amplifier path processes and amplifies the corresponding split input signal through an amplifier that is biased in class AB. The peaking amplifier path processes and amplifies the other split input signal through an amplifier that is biased in class C.

Each path has an input matching network 122/133, an amplifier 123/134, an output matching network 124/135, and a phasing line 125/136. The function of the input matching networks is to match the 50-ohm impedance at each port of the input splitter 110 to the input impedance of the carrier and peaking amplifiers in order to maximize the gains of the class AB carrier amplifier and the class C peaking amplifier. Note that each amplifier may be implemented using a single transistor device or a suitable combination of multiple transistors. The function of the output matching networks is to match the output impedance of the carrier and peaking amplifiers to 50 ohms for maximum available power. The phasing lines provide the proper amount of phase shift such that the impedance seen by the carrier amplifier is 100 ohms nominal when the peaking amplifier is not conducting, since the output impedance of the peaking amp is not infinite under this condition.

In addition, peaking amplifier path 130 has a quarter wavelength transmission line 132 at its input, while carrier amplifier path 120 has a quarter wavelength transmission line 126 at its output. The function of quarter wavelength transmission line 126 is to act as a quarter wave transformer. Thus, the impedance at the junction 140 between phasing line 136 and transmission line 150, when the peaking amplifier is not conducting, is raised by a factor of 4 as seen from the input of transmission line 126. For the case where the carrier and peaking amplifiers are identical, the impedance at junction 140 is 25 ohms so the impedance at the input of the quarter wavelength transmission line 126 is 100 ohms. The quarter wavelength transmission line 126 must be located at the output of the carrier amplifier, because it provides the load modulation to the carrier amplifier. When the peaking amplifier is not conducting, the load seen by the carrier amp is 100 ohms When the peaking amplifier is fully on, the load seen by the carrier amplifier is now 50 ohms, since the impedance at junction 140 has now increased from 25 ohms to 50 ohms. So, in summary, the load seen by the carrier amplifier has changed from 100 ohms to 50 ohms as the peaking amplifier state changed from non-conducting to fully conducting.

Quarter wavelength transmission line 132 is added in the peaking amplifier path in order for the signals that travel through paths 120 and 130 to have the same delay and therefore to add in phase at junction 140. This line is added at the input side of the peaking amplifier so that its insertion loss is not seen by the output of the peaking amplifier and thus more efficient operation is achieved.

Another quarter wavelength transmission line 150 is located after the signals from the two paths are combined at junction 140. The function of transmission line 150 is to transform the impedance at junction 140 to 50 ohms at the RF output. Thus, when the peaking amplifier is off, transmission line 150 transforms 25 ohms to 50 ohms and that is why its characteristic impedance Zₒ is 35 ohms (25 ohms=Zₒ²/50 ohms, so Zₒ=35 ohms).

FIGS. 2 and 3 shows two other conventional Doherty circuits. In FIG. 2, instead of an in-phase Wilkinson power splitter and a quarter wavelength transmission line in the peaking amplifier path, Doherty circuit 200 has a 3 dB quadrature hybrid power splitter 210 with a 50-ohm termination resistor 215 configured between ground and the hybrid splitter. The hybrid splitter 210 splits the input signal into two equal amplitude signals that are 90 degrees out of phase relative to each other. In FIG. 2, the signal at the input to the carrier amplifier has a 0-degree phase shift, while the signal at the input of the peaking amplifier has a 90-degree phase shift. The termination resistor 215 terminates the isolated port of the 3 dB hybrid coupler.

FIG. 3 shows an asymmetric Doherty circuit 300 having a 4.8 dB directional coupler 310 that performs a 2:1 split between the peaking amplifier path and the carrier amplifier path, such that peaking amplifier 334 is twice the size of carrier amplifier 323. For single-device amplifiers, an asymmetric circuit means that the carrier and peaking transistor sizes are not the same. For example, for a 2:1 asymmetric circuit, the peaking transistor is twice the size of the carrier transistor. This means that the RF power through the peaking transistor is twice the RF power through the carrier transistor. This is accomplished by using a 4.8 dB splitter at the input where ⅓ of the input power is directed to the carrier transistor and ⅔ of the input power is directed to the peaking transistor. The load modulation factor for a 2:1 asymmetric circuit is 3:1. Thus, the load seen by the carrier device is 150 ohms when the peaking transistor is off, and that load changes to 50 ohms when the peaking transistor is fully conducting. An asymmetric Doherty circuit is used for applications that require more backed off operation (9.5 dB) than symmetric circuits (6 dB). Furthermore, asymmetric circuits can be more efficient than symmetric circuits at the same back off.

### SUMMARY

Quarter wavelength transmission lines, such as passive transmission lines 132, 126, and 150 in Doherty circuit 100 of FIG. 1, are typically designed to rotate the center frequency of the desired operational frequency range by 90 degrees. Unfortunately, for signal frequencies other than the center frequency, the rotations applied by such transmission lines will differ from 90 degrees, which will degrade the performance of the Doherty circuit. For wideband operations (e.g., >100 MHz), that performance degradation can be significant for frequencies far from the center frequency.

For example, if Doherty circuit 100 of FIG. 1 is designed to cover the DCS and UMTS bands simultaneously (i.e., 1805-2170 MHz), then each of the quarter wavelength transmission lines 132, 126, and 150 would typically be designed for an electrical length of 90 degrees at the center frequency of 1987.5 MHz. For the particular implementation shown in FIG. 1 in which, at the 1987.5 MHz center frequency, phasing lines 125 and 136 and quarter wavelength transmission lines 126 and 132 are all 50-ohm elements and quarter wavelength transmission line 150 is a 35-ohm element, if peaking amplifier 134 is turned off, then the impedance seen by carrier amplifier 123 at the center frequency will be 100 ohms. At the low end of the band (i.e., 1805 MHz), however, the electrical length of each of transmission line is only about 81 degrees, instead of 90 degrees. As a result, the impedance seen by carrier amplifier 123 will now be only about 95 ohms, instead of 100 ohms. This impedance difference can cause carrier amplifier 123 to compress significantly differently at the low end of the band than at the center of the frequency band. As a result, the results at the band edges of upstream digital pre-distortion (DPD) will be degraded compared to the results of that DPD at the center of the band.

Similar problems exist for the other Doherty circuits shown in FIGS. 2 and 3.

In one embodiment, the present invention is a circuit comprising a power splitter, a carrier amplifier path, a peaking amplifier path, a power combiner, and control circuitry. The power splitter is configured to split an input signal into first and second signals.

The carrier amplifier path, which is configured to receive the first signal from the power splitter, comprises a first variable phase shifter in series with a carrier amplifier. The first variable phase shifter applies a first phase shift to the first signal, and the carrier amplifier amplifies the first signal.

The peaking amplifier path, which is configured to receive the second signal from the power splitter, comprises a second variable phase shifter in series with a peaking amplifier. The second variable phase shifter applies a second phase shift to the second signal, and the peaking amplifier amplifies the second signal.

The power combiner is configured to combine signals generated by the carrier and peaking amplifier paths to provide an output signal. The control circuitry is configured to control the first and second phase shifts applied by the first and second phase shifters to the first and second signals, respectively.

### BRIEF DESCRIPTION OF THE DRAWINGS

Other aspects, features, and advantages of the present invention will become more fully apparent from the following detailed description, the appended claims, and the accompanying drawings in which like reference numerals identify similar or identical elements.

FIGS. 1-3 show block diagrams of conventional Doherty circuits;

FIG. 4 shows a block diagram of a Doherty circuit according to one embodiment;

FIGS. 5 and 6 show block diagrams of analogs of the Doherty circuit of FIG. 4 for the conventional embodiments of FIGS. 2 and 3, respectively;

FIGS. 7 and 8 show schematic block diagrams of variable phase shifters that can be used to implement any of the variable phase shifters in any of the Doherty circuits of FIGS. 4-6;

FIGS. 9-11 show block diagrams of multi-stage analogs of the Doherty circuits of FIGS. 4-6, respectively; and

FIG. 12 shows a schematic block diagram of yet another variable phase shifter that can be used to implement any of the variable phase shifters in any of the Doherty circuits of FIGS. 4-6 and 9-11.

### DETAILED DESCRIPTION

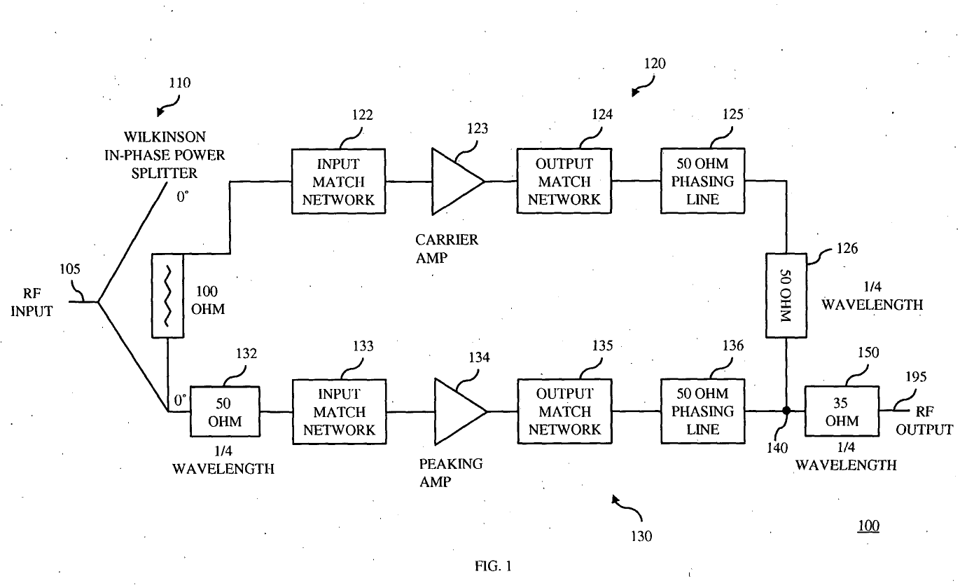

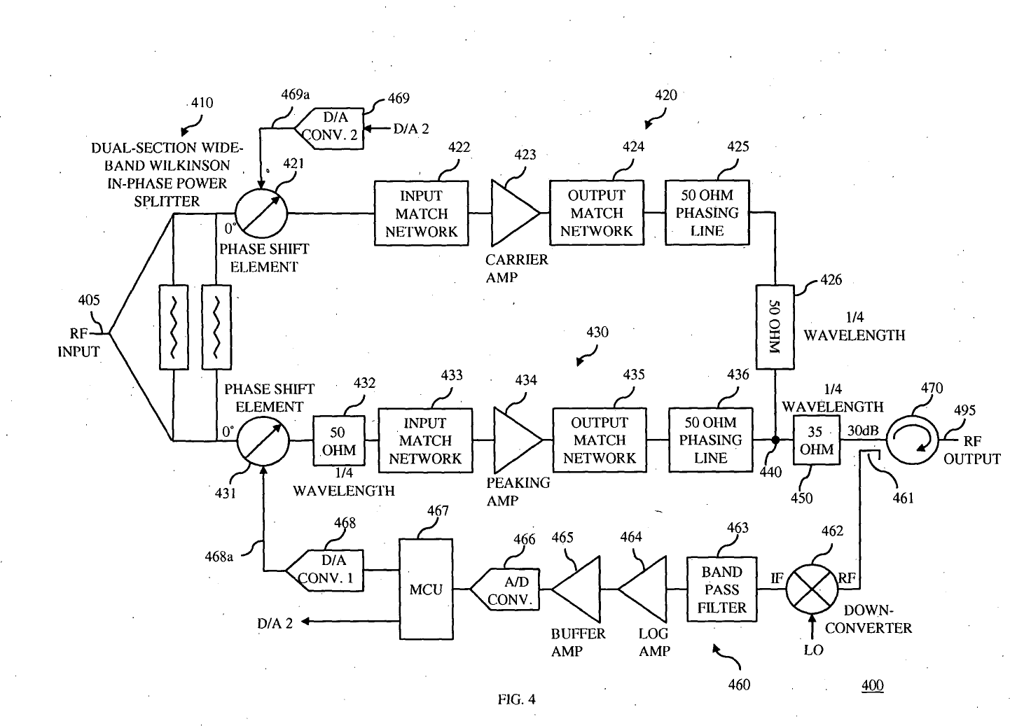

FIG. 4 shows a block diagram of a Doherty circuit 400 according to one embodiment. Like Doherty circuit 100 of FIG. 1, Doherty circuit 400 has a power splitter 410, two processing paths (carrier amplifier path 420 and peaking amplifier path 430), and a quarter wavelength transmission line 450 after the signals from the two processing paths are combined at node 440. Note that, in this embodiment, for high-bandwidth operation, power splitter 410 is a dual-section wide-band in-phase Wilkinson power splitter that evenly splits the RF input signal 405 between the carrier and peaking amplifier paths. In Doherty circuit 400, elements 422-426 in the carrier amplifier path and elements 432-436 in the peaking amplifier path are similar to corresponding elements in the carrier and peaking amplifier paths of Doherty circuit 100.

Unlike Doherty circuit 100, Doherty circuit 400 has independently controlled, variable phase shifters 421 and 431 at the inputs of the carrier and peaking amplifier paths, respectively. In addition, Doherty circuit 400 has control circuitry 460 for independently controlling the phase shifts applied by variable phase shifters 421 and 431. In particular, control circuitry 460 includes (e.g., 30 dB) tap 461, RF-to-IF downconverter 462, bandpass filter 463, logarithmic (log) amplifier 464, buffer amplifier 465, analog-to-digital (A/D) converter 466, digital (e.g., micro) controller 467, and digital-to-analog (D/A) converters 468 and 469.

In, operation, tap 461 taps off a small portion of RF output signal 495 as a feedback signal, downconverter 462 downconverts the tapped feedback signal from radio frequency (RF) to a desired intermediate frequency (IF) signal based on an appropriate local oscillator (LO) mixing signal, bandpass filter 463 filters out high- and low-frequency components in the IF feedback signal, log amplifier 464, having a wide dynamic range, and buffer amplifier 465 amplify the filtered IF feedback signal, A/D converter 466 digitizes the amplified IF feedback signal for processing by controller 467, which generates two digital control signals: one for variable phase shifter 421 in the carrier amplifier path and the other for variable phase shifter 431 in the peaking amplifier path. D/A converters 468 and 469 convert those two digital control signals into analog (e.g., voltage) control signals 468a and 469a for respective application to the two variable phase shifters. Circulator 470 is provided to isolate the rest of Doherty circuit 400, and especially control circuitry 460, from poor VSWRs (voltage standing wave ratios) presented by external loads (not shown), such as a transmit filter.

Note that, depending on the implementation, the IF signal may be a baseband signal. Note further that, in an alternative implementation in which the variable phase shifters are digital phase shifters, D/A converters 468 and 469 can be omitted. Similarly, in a different alternative implementation in which controller 467 is an analog processor, A/D converter 466 and D/A converters 468 and 469 can all be omitted. In addition, if the rest of the control circuitry can operate at the RF frequencies of the input signal, then downconverter 462 can also be omitted.

In one mode of operation, based on the feedback signal from tap 461, controller 467 generates the two control signals 468a and 469a so as to minimize spurious emissions in the RF output signal that would otherwise result from non-linear phase distortion vs. frequency due to the matching networks of the active devices as well as the quarter wavelength transmission lines and output phasing lines, whose phase shifts at the band edges differ from those at the band center (where Doherty circuit 400 is assumed to be optimized). In particular, downconverter 462, filter 463, and amplifiers 464 and 465 are designed and/or configured such that the signal applied to A/D converter 466 corresponds to the frequencies known to be associated with spurious emissions for the current operating frequency of Doherty circuit 400. In that case, controller 467 employs a gradient-based algorithm or a least-squares-based algorithm or other suitable algorithm to generate the two control signals 468a and 469a to drive the amplitude of its input signal towards zero. In this way, the pre-distortability of Doherty circuit 400 can be improved over a relatively wide bandwidth range. Note that information about the current operating frequency of Doherty circuit 400 (i.e., the current carrier frequency of RF input signal 405) may be conveyed out-of-band to a system controller (not shown) for Doherty circuit 400 that appropriately configures the configurable elements of control circuitry 460.

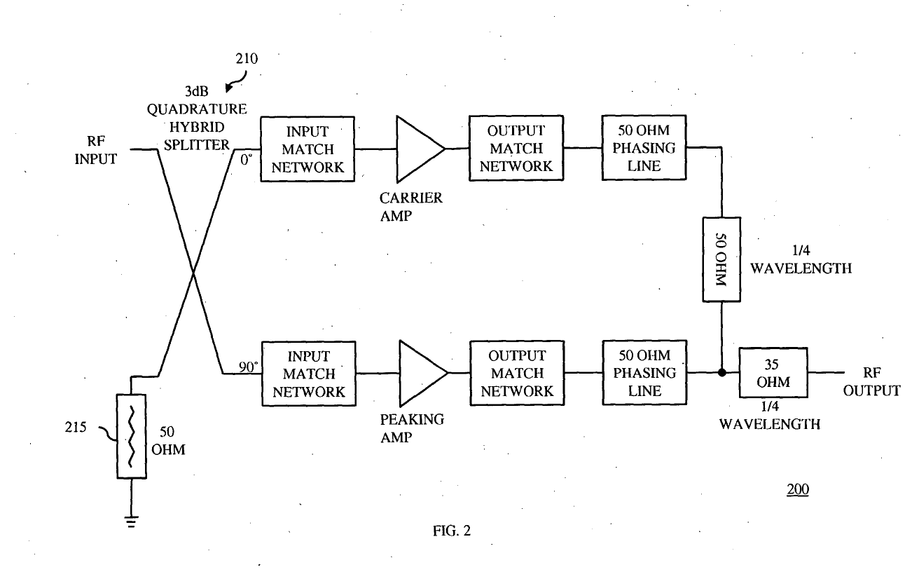

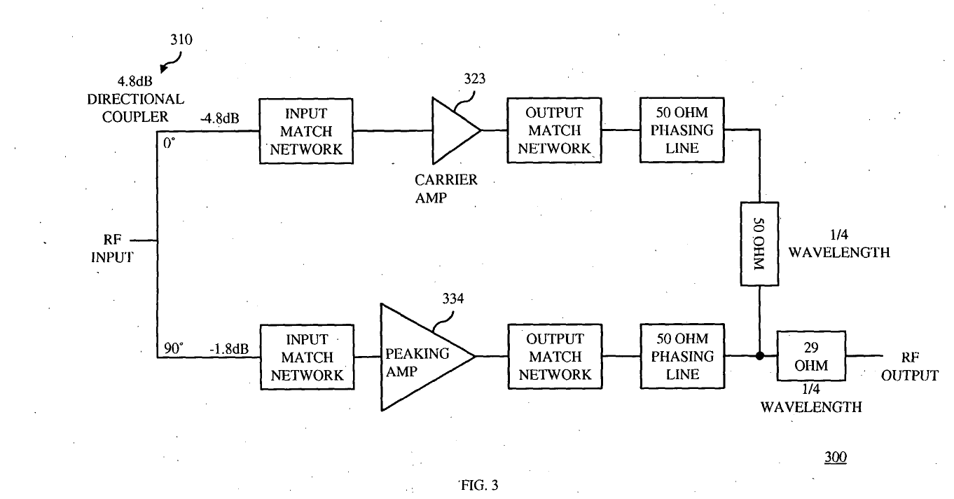

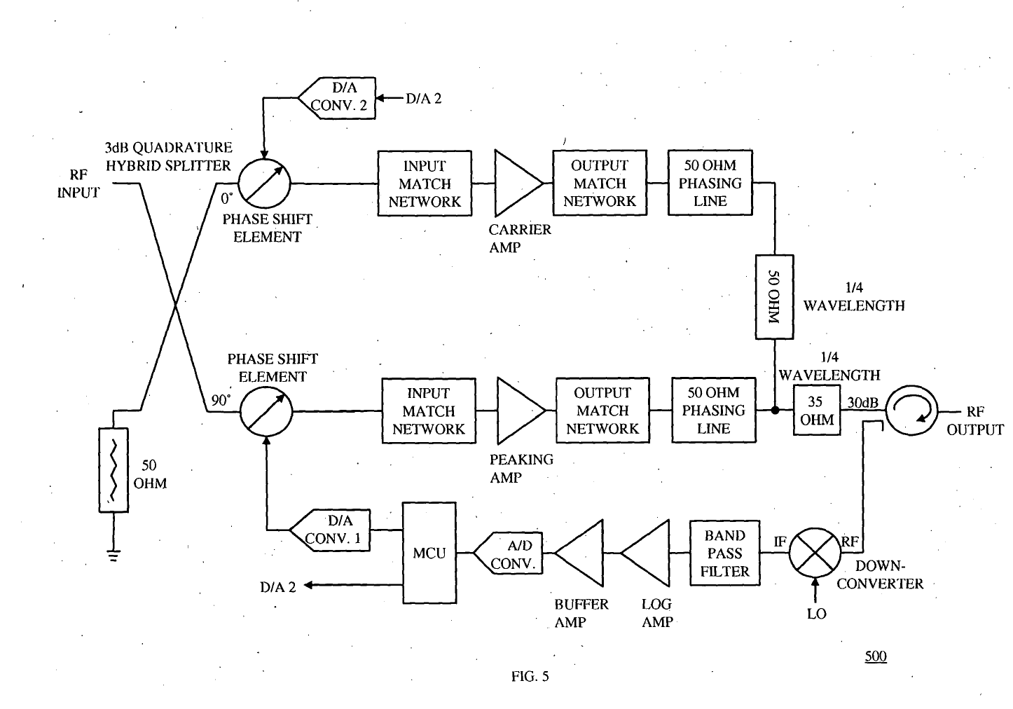

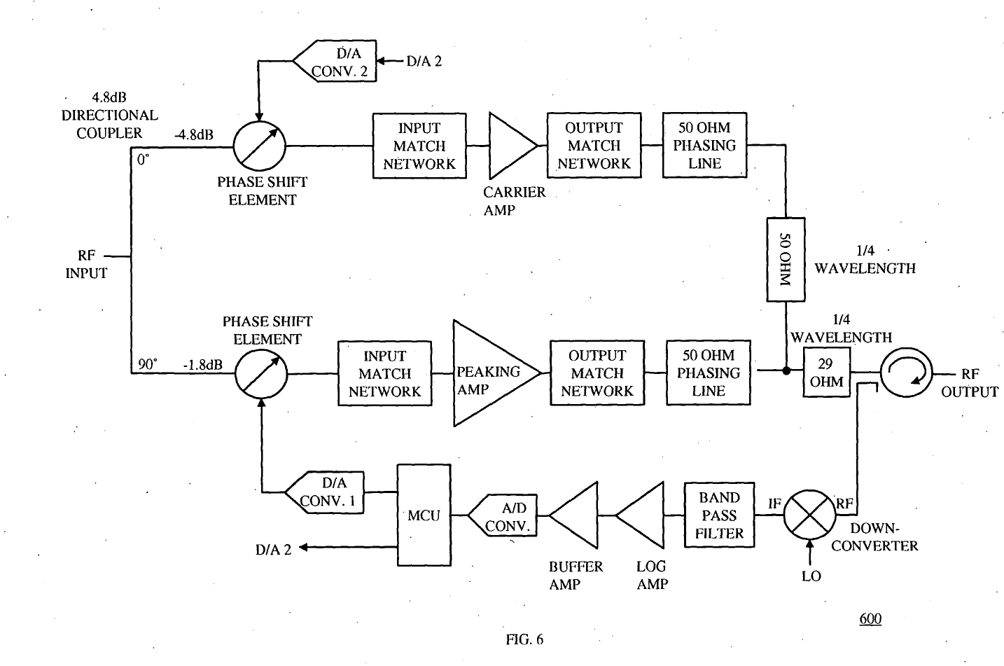

FIGS. 5 and 6 show block diagrams of analogs of Doherty circuit 400 of FIG. 4 for the conventional embodiments of FIGS. 2 and 3, respectively, where each of Doherty circuits 500 and 600 has independently controlled, variable phase shifters at the inputs of their carrier and peaking amplifier paths.

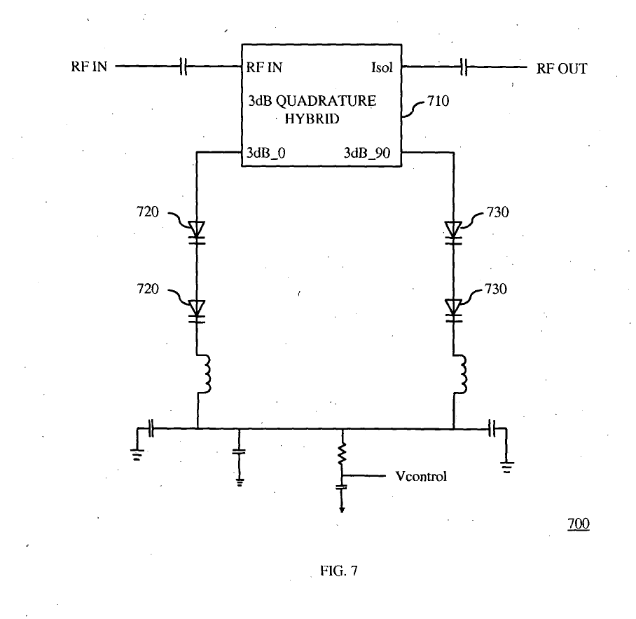

FIG. 7 shows a schematic block diagram of a variable phase shifter 700 that can be used to implement any of the variable phase shifters in any of the Doherty circuits of FIGS. 4-6. Variable phase shifter 700 uses 3 dB quadrature hybrid 710 along with varactor diodes 720 and 730 to implement the phase-shift function. The backs of the two varactors 720 on the left side of FIG. 7 “face” the backs of the two varactors 730 on the right side of FIG. 7 through hybrid 710 in a back-to-back configuration. This back-to-back configuration of the varactor diodes enables variable phase shifter 700 to achieve high linearity. A positive control voltage Vcontrol reverse biases the varactor diodes, such that the junction capacitance of the diodes varies as a function of the reverse voltage across them. As the control voltage changes, the phase of the signal through the hybrid also changes. Variable phase shifter 700 can be implemented such that inter-modulation distortions (IMDs) generated by variable phase shifter 700 are much less than IMDs generated by the corresponding, uncorrected Doherty circuit, even for relatively high power levels at the inputs to the carrier and peaking amplifier paths. Variable phase shifter 700 is described in further detail in U.S. Pat. No. 5,990,761, the teachings of which are incorporated herein by reference.

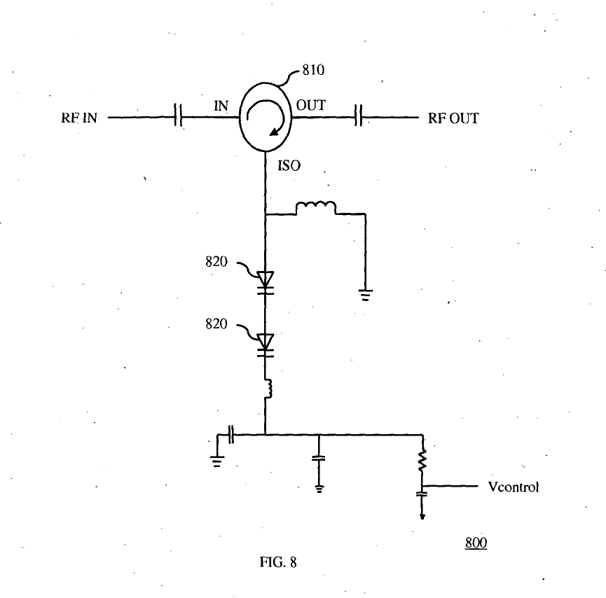

FIG. 8 shows a schematic block diagram of another variable phase shifter 800 that can be used to implement any of the variable phase shifters in any of the Doherty circuits of FIGS. 4-6. In this case, varactor diodes 820 are connected to the isolated port (ISO) of a three-terminal circulator 810. Again, a positive control voltage Vcontrol reverse biases the varactor diodes, such that the junction capacitance of the diodes varies as a function of the reverse voltage across them. As the control voltage changes, the phase of the signal through the circulator also changes. As with variable phase shifter 700, variable phase shifter 800 can be implemented such that IMDs generated by variable phase shifter 800 are much less than IMDs generated by the corresponding, uncorrected Doherty circuit, even for relatively high power levels at the inputs to the carrier and peaking amplifier paths.

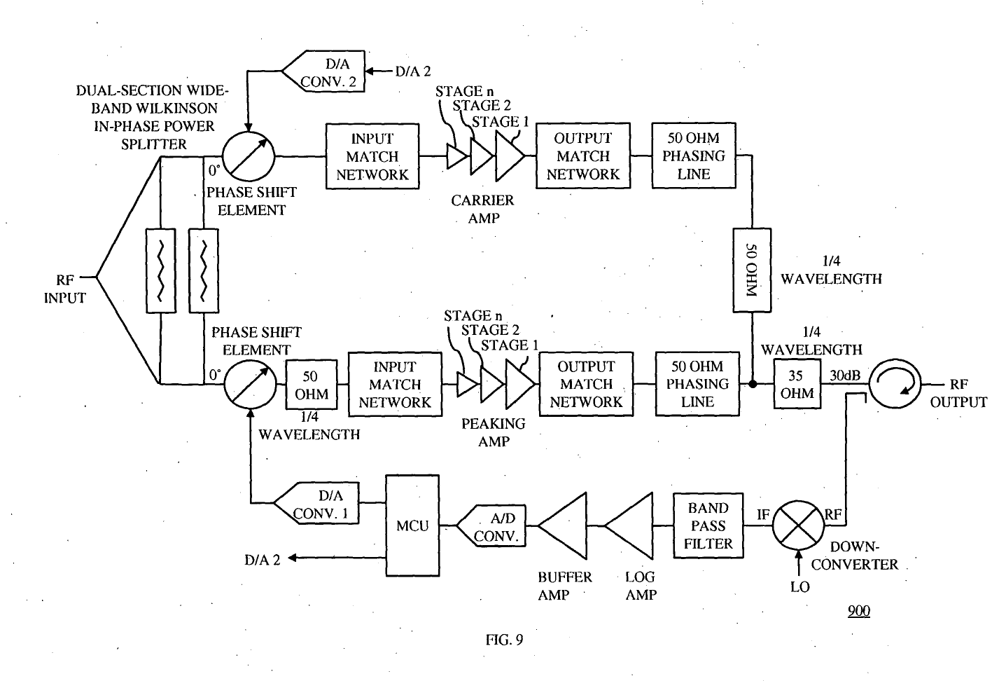

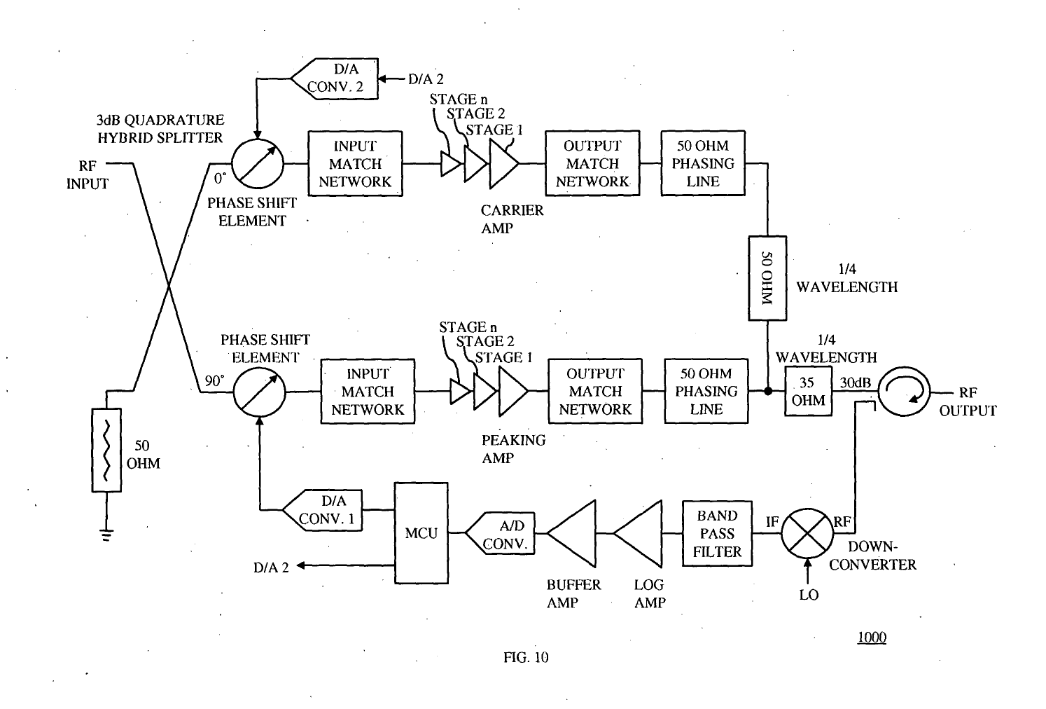

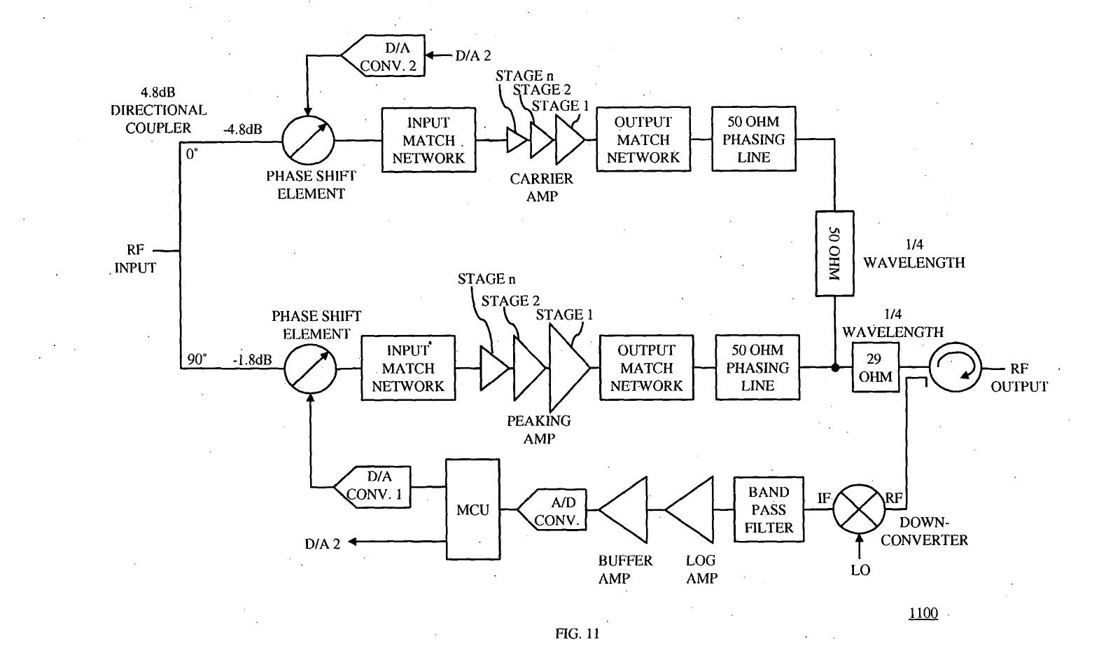

FIGS. 9-11 show block diagrams of multi-stage analogs of the Doherty circuits of FIGS. 4-6, respectively, where each of Doherty circuits 900, 1000, and 1100 has multiple (e.g., three) amplifier stages in each processing path.

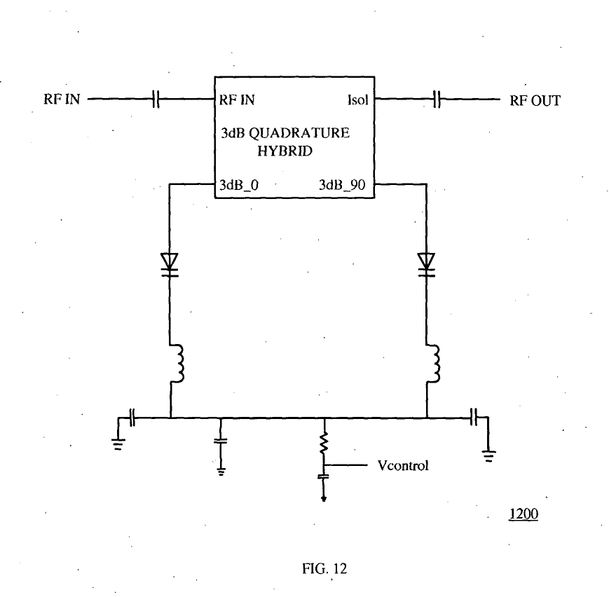

FIG. 12 shows a schematic block diagram of yet another variable phase shifter 1200 that can be used to implement any of the variable phase shifters in any of the Doherty circuits of FIGS. 4-6 and 9-11. Variable phase shifter 1200 may be particularly suitable for the multi-stage Doherty circuits of FIGS. 9-11, where the power level of the RF input signals may be. significantly lower than the power level of the RF input signals in the Doherty circuits of FIGS. 4-6.

### Alternatives

The present invention has been described in the context of Doherty circuits. A Doherty (amplifier) circuit consists of a class 13 primary or carrier stage in parallel with a class C auxiliary or peak stage. The input signal is split to drive the two amplifiers and a combining network sums the two output signals. Phase shifting networks are employed in the inputs and the outputs. During periods of low signal level, the class B amplifier efficiently operates on the signal and the class C amplifier is cutoff and consumes little power. During periods of high signal level, the class B amplifier delivers its maximum power and the class C amplifier delivers up to its maximum power.

The present invention can be implemented in the context of circuits other than Doherty circuits, including, for example, Sainton circuits. A Sainton (amplifier) circuit consists of a class C primary or carrier stage in parallel with a class C auxiliary or peak stage. The stages are split and combined through 90-degree phase shifting networks as in the Doherty amplifier. The unmodulated radio frequency carrier is applied to the control grids of both tubes. Carrier modulation is applied to the screen grids of both tubes. The bias point of the carrier and peak tubes is different, and is established such that the peak tube is cutoff when modulation is absent (and the amplifier is producing rated unmodulated carrier power) whereas both tubes contribute twice the rated carrier power during 100% modulation (as four times the carrier power is required to achieve 100% modulation). As both tubes operate in class C, a significant improvement in efficiency is thereby achieved in the final stage. In addition, as the tetrode carrier and peak tubes require very little drive power, a significant improvement in efficiency within the driver stage is achieved as well.

The present invention can also be implemented in the context of two class AB amplifiers that are quadrature hybrid combined. In general, the present invention can be applied to any amplifier circuit topology that uses printed transmission lines for providing adequate phase shift and/or impedance transformation for the purpose of combining signals and achieving high efficiency.

The present invention has many applications, including (without limitation) wide bandwidth, high linearity and efficiency amplifiers for use in remote radio heads (e.g., mounted on poles), active antennas, in building repeaters, pico stations, micro stations, base station amplifier systems such as transmit receive digital units that are, for example, forced air cooled and mounted in indoor frames, wireless devices, and TV broadcast amplifiers.

The present invention may be implemented as (analog, digital, or a hybrid of both analog and digital) circuit-based processes, including possible implementation as a single integrated circuit (such as an ASIC or an FPGA), a multi-chip module, a single card, or a multi-card circuit pack. As would be apparent to one skilled in the art, various functions of circuit elements may also be implemented as processing blocks in a software program. Such software may be employed in; for example, a digital signal processor, micro-controller, general-purpose computer, or other processor.

Also for purposes of this description, the terms “couple,” “coupling,” “coupled,” “connect.” “connecting,” or “connected” refer to any manner known in the art or later developed in which energy is allowed to be transferred between two or more elements, and the interposition of one or more additional elements is contemplated, although not required. Conversely, the terms “directly coupled,” “directly connected,” etc., imply the absence of such additional elements.

Also, for purposes of this description, it is understood that all gates are powered from a fixed-voltage power domain (or domains) and ground unless shown otherwise. Accordingly, all digital signals generally have voltages that range from approximately ground potential to that of one of the power domains and transition (slew) quickly. However and unless stated otherwise, ground may be considered a power source having a voltage of approximately zero volts, and a power source having any desired voltage may be substituted for ground. Therefore, all gates may be powered by at least two power sources, with the attendant digital signals therefrom having voltages that range between the approximate voltages of the power sources.

Signals and corresponding nodes or ports may be referred to by the same name and are interchangeable for purposes here.

Unless explicitly stated otherwise, each numerical value and range should be interpreted as being approximate as if the word “about” or “approximately” preceded the value of the value or range.

It will be further understood that various changes in the details, materials, and arrangements of the parts which have been described and illustrated in order to explain the nature of this invention may be made by those skilled in the art without departing from the scope of the invention as expressed in the following claims.

The use of figure numbers and/or figure reference labels in the claims is intended to identify one or more possible embodiments of the claimed subject matter in order to facilitate the interpretation of the claims. Such use is not to be construed as necessarily limiting the scope of those claims to the embodiments shown in the corresponding figures.

It should be understood that the steps of the exemplary methods set forth herein are not necessarily required to be performed in the order described, and the order of the steps of such methods should be understood to be merely exemplary. Likewise, additional steps may be included in such methods, and certain steps may be omitted or combined, in methods consistent with various embodiments of the present invention.

Although the elements in the following method claims, if any, are recited in a particular sequence with corresponding labeling, unless the claim recitations otherwise imply a particular sequence for implementing some or all of those elements, those elements are not necessarily intended to be limited to being implemented in that particular. sequence.

Reference herein to “one embodiment” or “an embodiment” means that a particular feature, structure, or characteristic described in connection with the embodiment can be included in at least one embodiment of the invention. The appearances of the phrase “in one embodiment” in various places in the specification are not necessarily all referring to the same embodiment, nor are separate or alternative embodiments necessarily mutually exclusive of other embodiments. The same applies to the term “implementation.”

The embodiments covered by the claims in this application are limited to embodiments that (1) are enabled by this specification and (2) correspond to statutory subject matter. Non-enabled embodiments and embodiments that correspond to non-statutory subject matter are explicitly disclaimed even if they fall within the scope of the claims.

What is claimed is:

1. A circuit (e.g., 400) comprising:
a power splitter (e.g., 410) configured to split an input signal (e.g., 405) into first and second signals;
a carrier amplifier path (e.g., 420) configured to receive the first signal from the power splitter, the carrier amplifier path comprising a first variable phase shifter (e.g., 421) in series with a carrier amplifier (e.g., 423), wherein:
the first variable phase shifter applies a first phase shift to the first signal; and
the carrier amplifier amplifies the first signal;
a peaking amplifier path configured to receive the second signal from the power splitter, the peaking amplifier path comprising a second variable phase shifter (e.g., 431) in series with a peaking amplifier (e.g., 434), wherein:
the second variable phase shifter applies a second phase shift to the second signal; and
the peaking amplifier amplifies the second signal;
a power combiner (e.g., 440) configured to combine signals generated by the carrier and peaking amplifier paths to provide an output signal; and
control circuitry (e.g., 460) configured to control the first and second phase shifts applied by the first and second phase shifters to the first and second signals, respectively.

2. The invention of claim 1, wherein the circuit is a Doherty circuit.

3. The invention of claim 1, wherein the control circuitry independently controls the first and second phase shifters.

4. The invention of claim 1, wherein the control circuitry is configured to control the first and second phase shifters based on a feedback signal tapped from the output signal.

5. The invention of claim 1, wherein:
the circuit is a Doherty circuit;
the control circuitry independently controls the first and second phase shifters; and the control circuitry is configured to control the first and second phase shifters based on a feedback signal tapped from the output signal.
